(19) United States
(12) Patent Application Publication
(10) Pub. No.: US 2023/0099584 A1
(43) Pub. Date: Mar. 30, 2023

(54) CIRCUIT AND METHOD OF TRANSMITTING DIGITAL DATA WITH ERROR DETECTION

(71) Applicant: Analog Devices International Unlimited Company, Limerick (IE)

(72) Inventors: John HAYDEN, Jamaica Plain, MA (US); Abhinav Kumar Dikshit, Bengaluru (IN); Benno Kusstatscher, Munich (DE)

(21) Appl. No.: 17/956,387

(22) Filed: Sep. 29, 2022

(30) Foreign Application Priority Data
Sep. 29, 2021 (DE) 10 2021 125 318.7

(51) Int. Cl. G06F 7/487

(52) U.S. Cl. CPC G06F 7/4876; G06F 7/4873

(57) ABSTRACT

There is disclosed a system for transmitting digital data with error detection, the system comprising a sender, configured to receive source data and to send transfer data, and a receiver configured to receive the transfer data and to output result data, wherein the sender is further configured to receive the source data, to numerically multiply the source data by an integer number greater than 2, and to output the multiplied source data as the transfer data, and wherein the receiver is further configured to receive the transfer data, to check if dividing the transfer data by the integer number results in an integer result, and, if the checking fails, to output an error indication, and, if the checking succeeds, to output the transfer data divided by the integer number as the result data. Also, a corresponding method is disclosed.

### CROSS-REFERENCE TO RELATED APPLICATIONS

The present application claims priority to, and the benefit of, German Patent Application No. 10 2021 125 318.7, Filed Sep. 29, 2021 and entitled “Transmitting Digital Data with Error Detection,” the contents of which are hereby incorporated by reference in their entireties.

### FIELD OF INVENTION

The present disclosure is directed at systems and methods for transmitting digital data with error detection. The present disclosure is also directed at systems and methods for transmitting and processing digital data with error detection.

### BACKGROUND

FIG. 1 shows an example of one or more signal processing functions f(x) that are performed in a computing unit 10. The signal processing functions f(x) operate on an input signal x. The result of this processing is an output signal z. In the example shown in FIG. 1, the signal processing functions may be unprotected, meaning neither permanent nor transient errors, like a single event upset (SEU), may be detected by the receiver. Examples of a single event upset may include an unintended change of state caused by one or more ionizing particles (e.g., ions, electrons, protons, etc.). One example of such an error is a soft error where a perturbation of a flip-flop state occurs. Such a change in the state in a flip-flop may cause one or more errors in the output signal z. In the shown example, however, such error may be undetected. No error flag may be made available to indicate an error. This applies also to functions that are combinatorial, sequential or both, including implementations using intermediate values and/or feedback values stored in registers.

While there are applications where such scenario is acceptable, this may no longer the case when the signal processing functions are used in a functional safety context. Here, undetected errors in the output signal z may cause violation of a safety goal and must therefore be avoided. It should be noted that while detection of errors is a safety requirement, a corresponding correction may or may not be a safety requirement.

FIG. 2 shows an architecture where the input signal x is protected, i.e. it is possible to identify errors in the output signal z. The input signal x is protected by a protection unit 12 which combines the input signal x with a protection signal w using a protection circuit P(x) that produces a protected input signal X. A protected input signal X has a number of properties useful in an environment that relies on safety (e.g. applications where errors need to be detected).

First, the protected input signal X may losslessly and reversibly contain some or all the information in input signal x. This means that the information content of the input signal x may be recovered from the protected input signal X. Second, the protected input signal X may introduce informational redundancy that may be used to identify and/or recover from an error. The informational redundancy allows to check for the accuracy of the information contained in the protected input signal X. Third, this informational redundancy may persist through some signal processing. This means that even though the protected input signal X will be subjected to signal processing, the informational redundancy required to identify at least one error may be maintained. Thus, some number of bit errors may be detected, e.g. caused by permanent or transient faults, in the protected input signal X, up to a maximum number of errors. Fourth, it may be possible to extract the information of the input signal x that is contained in the protected input signal X, at least in the case where no errors have occurred.

As a next step, the protected input signal X may be provided to the computing unit 10 where a modified signal processing function f′(X) is applied. In some aspects, the signal processing function f(x) is modified to operate on protected input signals and produce protected output signals. The result of this processing is output as a protected output signal Z. The protected output signal Z is provided to an inverse protection unit or unprotection unit 14 which, by applying an inverse protection function or unprotection function P⁻¹(Z), produces an output signal z. When processing the protected output signal Z, the unprotection unit 14 may generate the output signal z, and/or provide an error detection flag errdet, which indicates, at least, whether an error in the protected output signal Z has been detected. In some implementations, the unprotection unit 14 may indicate the number of errors identified and/or that a predetermined threshold of a maximum number of errors has been exceeded. It is noted that the protection that is being performed can also be understood in the sense of a type of watermarking to achieve safety.

In some aspects, the integrity level of the architecture may be described by a Hardware Fault Tolerance (HFT) number. The HFT number may count the number of hardware faults the architecture can tolerate and still satisfy the following three requirements. First, if there are zero errors in the protected signals X, Z, or any intermediate values within f′(X), i.e. no bits are corrupted by any errors (permanent or transient), the error detection flag errdet shall be de-asserted, and the state of the output signal z shall be equal to the original architecture's output signal z shown in FIG. 1.

Second, if the number of bits and/or states in the protected signals X, Z, or any intermediate values within f′(X) that are corrupted by an error (permanent or transient) is between 1 and HFT (inclusive), the error detection flag errdet shall be asserted. The state of the output signal z may be unspecified and different from the output of the original architecture signal z shown in FIG. 1.

Third, if the number of bits or states in the protected signals X, Z, or any intermediate values within f′(X) that are corrupted by an error (permanent or transient) exceeds HFT, the error detection flag errdet and the state of the output signal z are both unspecified and the output signal z may be expected to be different from the original architecture's output signal z shown in FIG. 1. Other criteria may also be implemented according to aspects of the present disclosure.

In certain automotive functional safety applications, a HFT number of one may be required. This means that the system may be configured to detect a single soft or hard error (detection), while it may or may not be necessary to produce an error-free result (correction). The detection capability may enable the system to attain a predefined safe state within the appropriate safety interval.

Conventional techniques may exist to detect single errors in processing at the cost of a full redundancy (e.g., a factor of 2, in some axis (area, power, time)), for example, via dual-core lockstep processor architectures or dual redundant software implementations. Other techniques may exist to detect or even correct one or more errors when no signal processing is intended, such as in communication, transport fabric, or storage. Examples may include parity, error checking and correction (ECC), checksum hashes, or cyclic redundancy checks (CRCs).

More specifically, an aspect to obtain the protected input signal X may be to calculate a checksum of the input signal x or of elements of the input signal x. This is may be done by adding one or more parity bits to the input signal x or, if it is desired to be able to correct an identified error, by applying error checking and correction (ECC). However, these known methods have their limitations.

As shown in FIG. 3, and referring to FIGS. 1 and 2, an aspect may include concatenating ECC bits to the input data variables x and y and attempting to add the resulting bit vectors X and Y in an ordinary adder. While the values X and Y may contain information redundancy added by the ECC generation unit, the result of the computing unit, here an arithmetic logic unit (ALU), may not bear a meaningful (reversible) relation to the desired result x+y, and the resulting simple sum of ECC bits is not likely to be the proper ECC code for the sum (x+y). As such, single bit errors in X or Y may not be consistently detected in this configuration. Thus the architecture fails to provide the property of protection that survives the simple addition mathematical operator.

It is an object of the present disclosure to provide systems and methods that achieve a detection of at least a single-fault with a reduced incremental area, power or time overhead on the architecture, i.e. with significantly less than a factor of 2 over an architecture that does not allow to identify errors. Further, it is an object that the systems and methods allow the protected signal to undergo at least a predetermined set of signal processing steps without losing the capability to detect at least one error.

### SUMMARY

Aspects of the present disclosure include a signal processing circuit having a sender circuit configured to receive an input signal, transform the input signal to a first protected signal by multiplying an input value of the input signal by a first integer number greater than 2, and transmit the first protected signal, a receiver circuit configured to receive a second protected signal, transform the second protected signal to an output signal by dividing a protected value of the second protected signal by a second integer number greater than 2, determine whether an output value of the output signal is an integer number, and transmit the output signal in response to determining that the output value is an integer number, or transmit an error signal in response to determining that the output value is not an integer number.

Aspects of the present disclosure include a method of processing signals including receiving an input signal, transforming the input signal to a first protected signal by multiplying an input value of the input signal by a first integer number greater than 2, transmitting the first protected signal, receiving a second protected signal, transforming the second protected signal to an output signal by dividing a protected value of the second protected signal by a second integer number greater than 2, determining whether an output value of the output signal is an integer number, and transmitting the output signal in response to determining that the output value is an integer number, or transmitting an error signal in response to determining that the output value is not an integer number.

Aspects of the present disclosure a non-transitory computer readable medium having instructions stored therein that, when executed by a processor, cause the processor to: cause a sender circuit to: receive an input signal, transform the input signal to a first protected signal by multiplying an input value of the input signal by a first integer number greater than 2, and transmit the first protected signal, and cause a receiver circuit to: receive a second protected signal, transform the second protected signal to an output signal by dividing a protected value of the second protected signal by a second integer number greater than 2, determine whether an output value of the output signal is an integer number, and transmit the output signal in response to determining that the output value is an integer number, or transmit an error signal in response to determining that the output value is not an integer number.

There is provided a system for transmitting digital data with error detection, the system comprising a sender, configured to receive source data and to send transfer data, and a receiver configured to receive the transfer data and to output result data, wherein the sender is further configured to receive the source data, to numerically multiply the source data by an integer number greater than 2, and to output the multiplied source data as the transfer data, and wherein the receiver is further configured to receive the transfer data, to check if dividing the transfer data by the integer number results in an integer result, and, if the checking fails, to output an error indication, and, if the checking succeeds, to output the transfer data divided by the integer number as the result data.

According to a further aspect there is provided a method for transmitting digital data with error detection, the method comprising the steps of: receiving source data; numerically multiplying the source data by an integer number greater than 2; sending the multiplied source data as transfer data; receiving the transfer data; checking if dividing the transfer data by the integer number results in an integer result, and outputting, if the checking fails, an error indication, and, if the checking succeeds, the transfer data divided by the integer number as the result data.

According to a further aspect there is provided a system for transmitting and processing digital data with error detection, the system comprising a first sender configured to send first source data, a second sender configured to send second source data, a first computing unit configured to perform a multiplication operation on each of the first and second source data resulting in first and second modified source data, respectively, wherein the multiplication operation is configured to numerically multi-ply by an integer number greater than 2, a second computing unit configured to perform a mathematical operation using the first and second modified source data as input and providing transfer data as output, and a receiver configured to receive the transfer data and to output result data, wherein the receiver is configured to receive the transfer data, to check if dividing the transfer data by the integer number results in an integer result, and, if the checking fails, to output an error indication, and, if the checking succeeds, to output the transfer data divided by the integer number as the result data, wherein the result data, if the checking succeeded, equals a result of the mathematical operation using the first and second source data as input.

According to a further aspect there is provided a method for transmitting and processing digital data with error detection, the method comprising the steps of: receiving first and second source data; numerically multiplying each of the first and second source data resulting in first and second modified source data, respectively, wherein the multiplying numerically multiplies the source data by an integer number greater than 2; performing a mathematical operation using the first and second modified source data as input and providing transfer data as output; receiving the transfer data; checking if dividing the transfer data by the integer number results in an integer result, and outputting, if the checking fails, an error indication, and, if the checking succeeds, the transfer data divided by the integer number as the result data, wherein the result data, if the checking succeeded, equals a result of the mathematical operation using the first and second source data as input.

According to a further aspect there is provided a computer-readable medium having thereon instructions which, when executed by computer, perform the steps of a method for transmitting digital data with error detection as described above.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various implementations discussed in the present document.

FIG. 1 illustrates generally a system where an input signal x is processed into an output signal z.

FIG. 2 illustrates generally a system where an input signal x is processed into an output signal z making use of a protection unit and an unprotection unit.

FIG. 3 illustrates generally a system where a mathematical processing of two input signals x,y making use of a protection unit and an unprotection unit leads to a meaningless result.

FIG. 4 illustrates generally a system that employs an exemplary protection circuit and uses a first exemplary arithmetic circuit.

FIG. 5 illustrates generally the system of FIG. 4 that employs the exemplary protection circuit and uses a second exemplary arithmetic circuit.

FIG. 6 illustrates generally a first exemplary implementation of a system for transmitting digital data with error detection.

FIG. 7 illustrates generally a second exemplary implementation of a system for transmitting digital data with error detection.

FIG. 8 illustrates generally a third exemplary implementation of a system for transmitting digital data with error detection.

FIG. 9 illustrates generally a fourth exemplary implementation of a system for transmitting digital data with error detection.

FIG. 10 illustrates generally a first exemplary implementation of a method for transmitting digital data with error detection.

FIG. 11 illustrates generally a second exemplary implementation of a method for transmitting digital data with error detection.

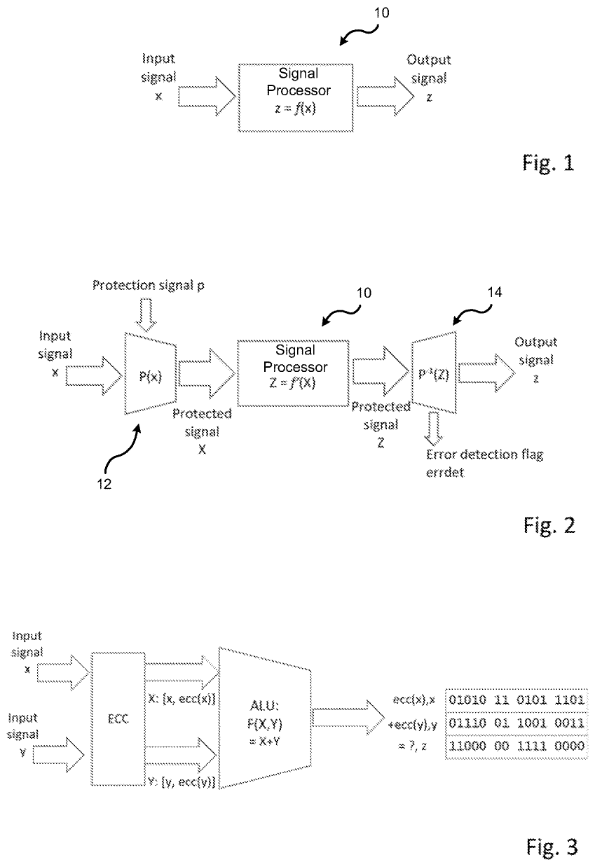

### DETAILED DESCRIPTION

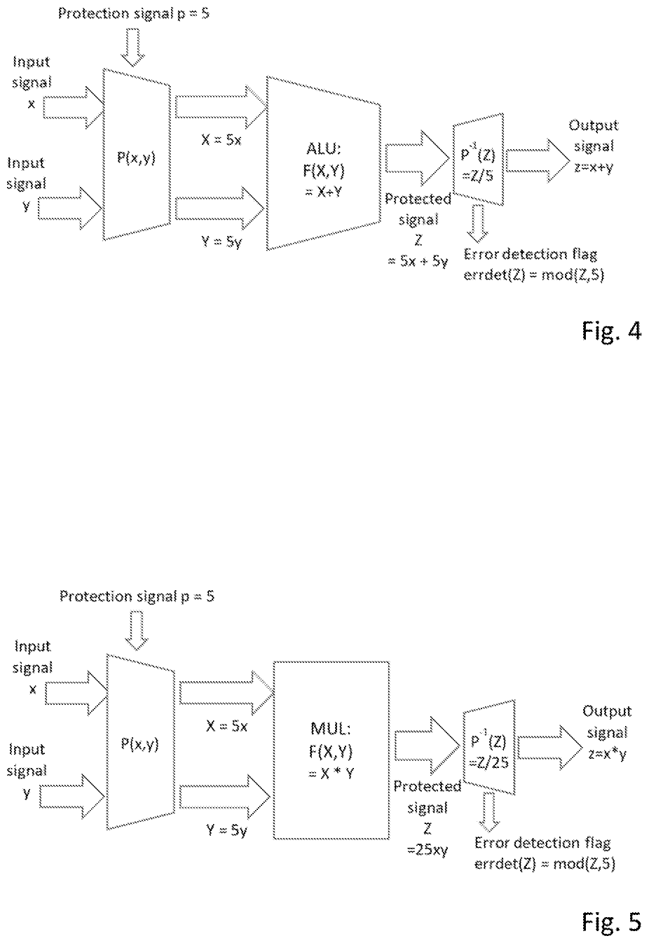

To explain one aspect of the present disclosure, reference is made to FIG. 4 which shows a diagram that explains a first example. In the first example, two input signals x and y are provided to a protection circuit P(x,y). More or less input signals may be implemented according to aspects of the present disclosure. The protection circuit P(x,y) is may multiply one or both of the input signals (x or y) by a protection signal, for example a signal having a value of the binary constant 5. The two input signals x and y may be understood as source data. The protection circuit P(x,y) may transform the input signals (x and/or y) into protected signals X and Y. Here, the bit widths may increase by three bits due to the selected protection signal having a value of binary constant of 5. The generated protected signals X and Y may be understood as modified source data.

In this operation by the protection circuit P(x,y), information redundancy may be introduced, as two distinct images separated by a shift of two bits are added together. The value 5 has two nonzero bits in its binary representation, i.e. 0b101. Equivalently, the state space of each protected signal X and Y is now less dense: only one in five states are legal, namely all the states with modulo 5 of zero. All other states are illegal. Notably, since the values of all bit positions are not divisible by 5, every single bit error will result in detectably perturbing the value resulting in a nonzero modulo-5.

The protection property is preserved across the signal processing operation of addition shown in this example as Z=F(X, Y)=X+Y. This remains applicable as long as there is no truncation, i.e. all information is preserved. Truncation can be avoided in a real-life implementation by choosing variables with sufficient bits for the whole range of values that are to be expected. In the protected result signal Z, the same checking, whether modulo-5 equals zero, serves to detect any single bit error.

The reversibility property may be maintained. The payload contents of the protected signal, i.e. the result data, may be losslessly retrieved by dividing the transfer data by 5, if no error was detected (i.e. the division by 5 rendered in integer number). In some examples, a receiver circuit receiving the protected signal may transform the protected signal using methods described above (e.g., modulo-5). Based on the results of the transformation, the receiver circuit may determine the presence or absence of error. In some instances, if the receiver circuit detects an error, the receiver circuit may transmit an error signal indicating the detection of the error.

It is noted that the protection operation of multiplication by 5 may be implemented by a simple shifting the source data by two bits to the left and adding the original value from the source data to the shifted value. Correspondingly, the unprotection operation of divide-by-5 may be conveniently implemented by multiplying the operand by ⅕, to a precision sufficiently adequate to discriminate quantization error from a single LSB error in the operand.

Turning now to FIG. 5 which shows a diagram that explains a second example. The previous explanations regarding the protection circuit and the checking for at least one error apply to this example as well.

In this second example, the circuit operation may be multiplication. The multiplication of two protected numbers will result in the product being scaled by the square of the protection function associated with the protection circuit, here, 5*5=25. In order to detect single errors, the modulo-5 operation described above, i.e. mod(Z,5), is sufficient. To recover the payload result, i.e. z=F(x,y), the raw multiplier result may be divided by 25, i.e. z=Z/25. It is noted that the mod(Z,5) and the Z/25 operations may be performed in parallel.

In particular, if the product is to be truncated by dropping least significant bits (LSBs) as it is done in fractional arithmetic, the Z/25 operation does not need to process the entire double-width product. Instead, it may be truncated and then divided by 25 starting at the most significant bit (MSB). If the product z is to be used in subsequent protected operations, it must be protected (or protected again), provided that the modulo-5 check on the full product Z has been performed.

The properly protected product Z′=5xy may be generated in one of at least two methods. If it is intended to retain full precision/range, Z=25xy is divided by 5 and all resulting bits (double precision) are retained. The resulting product Z′=5*xy and exhibits the same protection function as the input signals X and Y. If a reduced precision/range is acceptable, Z=25xy is divided by 25, the desired range of bits (by integer MSB-truncation or fractional rounding) is extracted, and then the result is protected again by multiplying by 5.

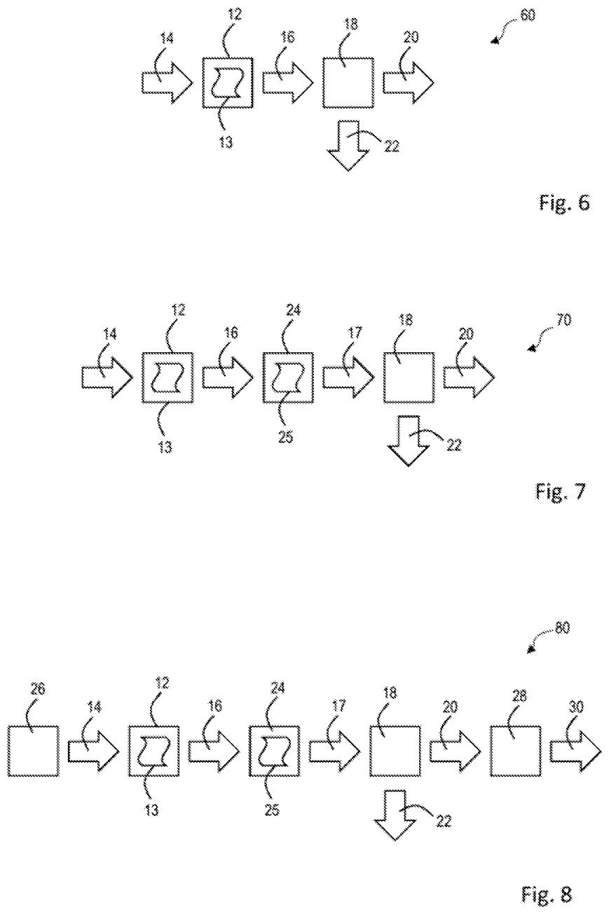

FIG. 6 illustrates a first exemplary implementation of a system 60 for transmitting digital data with error detection. The system 60 may include a sender 12 that is configured to receive source data 14 and to send transfer data 16. System 10 further comprises a receiver 18 that is configured to receive the transfer data 16 and to output result data 20.

Sender 12 is further configured to receive the source data 14 and to numerically multiply the source data 14 by an integer number greater than 2 using a multiplication operation 13. The multiplied source data is then output by the sender 12 as the transfer data 16.

Receiver 18 is further configured to receive the transfer data 16 and to check if dividing the transfer data 16 by the integer number that was used in the multiplication operation 13 results in an integer result. If the checking fails, i.e. the division does not render an integer result, an error indication 22 is output. If the checking succeeds, i.e. the division renders an integer result, the transfer data 16 divided by the integer number that was used in the multiplication operation 13 is output as the result data 20.

In some exemplary implementations, the error indication 22 is output as the result data, e.g. by outputting at least one of a predetermined value, a value below a predefined threshold, a value above a predefined threshold, a value within a predefined range, or a value outside a predefined range.

It is understood that the terms “division” and “dividing” encompass any type of implementation including, without limitation, the modulo operation which indicates that the result of a division is an integer result, if the remainder is zero, and that the result of a division is not an integer result, if the remainder is not zero.

FIG. 7 illustrates a second exemplary implementation of a system 70 for transmitting digital data with error detection. System 70 has a similar structure as that of system 60, and all previous explanations apply to system 70 as well. System 70 comprises a computing unit 24 which performs a mathematical operation 25 on the transfer data 16.

The mathematical operation 25 comprises one or more of an addition, a subtraction, a multiplication or a comparison. In some exemplary implementations, the mathematical operation 25 comprises only one or more of an addition, a subtraction, a multiplication or a comparison. More specifically, in the exemplary implementation of FIG. 4, the mathematical operation 25 is an addition, and in the exemplary implementation of FIG. 5, the mathematical operation 25 is a multiplication.

For the sake of simplicity, the data output by the computing unit 24 is again referred to as transfer data 17 as it is data that is being transferred between the sender 12 and the receiver 18. However, it is noted that the transfer data 17 being output by the computing unit 24 will typically be different from the transfer data 16 that is input into the computing unit 24. If a differentiation is sought, the transfer data 17 may be called modified transfer data 17 for all purposes after it is output by the computing unit 24.

FIG. 8 illustrates a third exemplary implementation of a system 80 for transmitting digital data with error detection. System 80 has a similar structure as that of system 70, and all previous explanations apply to system 80 as well. System 80 comprises a sensor 26 which acquires the source data 14 and sends the source data 14 to the sender 12. System 80 further comprises a controller 28 configured to receive the result data 20 and generate a command 30 making use of the result data 20.

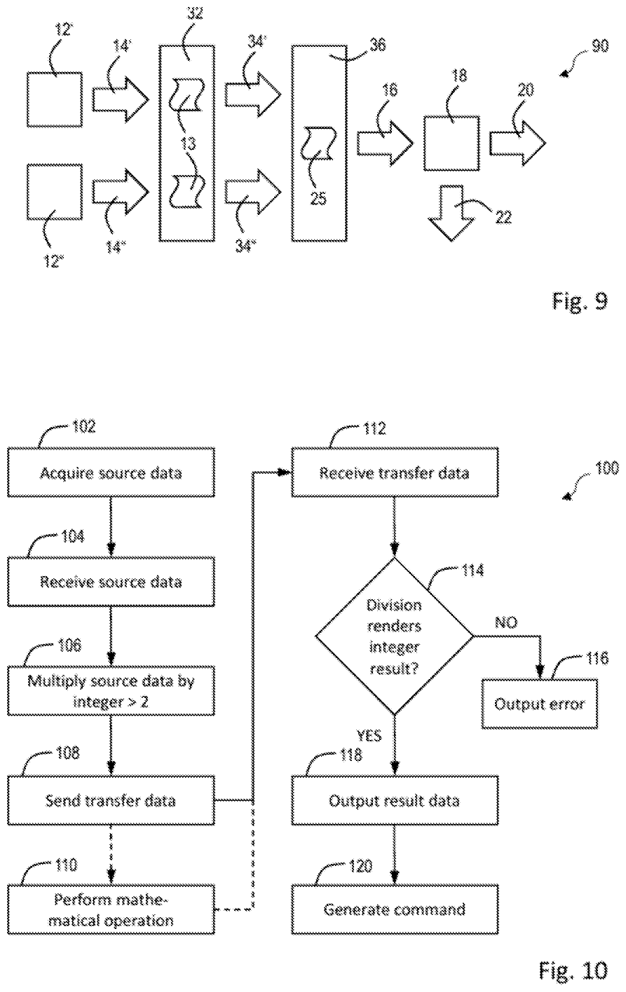

FIG. 9 illustrates a fourth exemplary implementation of a system 90 for transmitting digital data with error detection, system 90 comprising a first sender 12′ that sends first source data 14′ and a second sender 12″ that sends second source data 14″. System 90 further comprises a first computing unit 32 that performs a multiplication operation 13 on each of the first and second source data 14′, 14″ resulting in first and second modified source data 34′, 34″, respectively. The multiplication operation 13 is configured to numerically multiply by an integer number greater than 2.

System 90 further comprises a second computing unit 36 configured to perform a mathematical operation 25 using the first and second modified source data 34′, 34″ as input and providing transfer data 16 as output. System 90 also comprises a receiver 18 configured to receive the transfer data 16 and to output result data 20. Receiver 18 receives, as explained in connection with the previous implementations, transfer data 16 to check if dividing the transfer data 16 by the integer number that was used in the multiplication operation 13 results in an integer result. If the checking fails, an error indication 22 is output by the receiver 18.

If the checking succeeds, the transfer data 16 divided by the integer number that was used in the multiplication operation 13 is output by the receiver 18 as the result data. The result data 20, if the checking succeeds, equals a result of the mathematical operation 25 using the first and second source data 14′, 14″ as input.

It is understood that any number of input operands may be used, even though only one and two inputs are shown in FIGS. 8 and 9 for the sake of simplicity. It is within the scope and spirit of the present disclosure that a summation or dot product of vectors of input data can be performed.

FIG. 10 illustrates a first exemplary implementation of a method 100 for transmitting digital data with error detection. Method 100 starts with optional step 102 of acquiring source data 14, e.g. using a sensor 26. In step 104 the source data 14 is received, and in step 106 source data 14 is numerically multiplied the by an integer number greater than 2 before the multiplied source data is sent as transfer data 16 in step 108, e.g. using a sender 12.

In optional step 110 a mathematical operation 25 is performed on the transfer data 16. As explained above, for the sake of simplicity, the data output by optional step 110 is again referred to as transfer data 16. In step 112 transfer data 16 is received, e.g. using a receiver 18. In step 114 it is checked if dividing the transfer data 16 by the integer number that was used in the multiplication operation 13 results in an integer result.

If the checking fails, an error indication 22 is output in step 116, and, if the checking succeeds, the transfer data 16 divided by the integer number that was used in the multiplication operation 13 is output as the result data 20 in step 118. In optional step 120 a command 30 is generated making use of the result data 20.

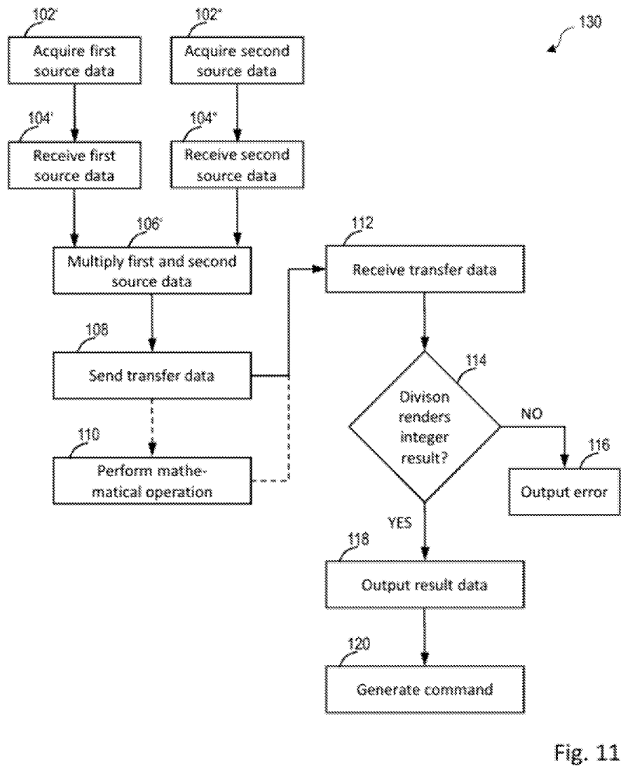

FIG. 11 illustrates a second exemplary implementation of a method 130 for transmitting digital data with error detection. Method 130 starts with optional steps 102′ and 102″ of acquiring first and second source data 14′, 14″, respectively, e.g. using sensors. In steps 104′ and 104″ the first and second source data 14′, 14″, is received, respectively.

In step 106′ the first and second source data 14′, 14″, is numerically multiplied by an integer number greater than 2 before sending the multiplied first and second source data. In other words, a multiplication operation 13 is performed using the first and second source data as input and providing transfer data 16 as output. Then, in step 108, the transfer data 16 is sent, e.g. using senders 12′ and 12″.

In optional step 110 a mathematical operation 25 is performed on the transfer data 16. As explained above, for the sake of simplicity, the data output by optional step 110 is again referred to as transfer data 16. In step 112 transfer data 16 is received, e.g. using a receiver 18. In step 114 it is checked if dividing the transfer data 16 by the integer number that was used in the multiplication operation 13 results in an integer result.

If the checking fails, an error indication 22 is output in step 116, and, if the checking succeeds, the transfer data 16 divided by the integer number that was used in the multiplication operation 13 is output as the result data 20 in step 118. In optional step 120 a command 30 is generated making use of the result data 20.

In some exemplary aspects the invention provides a method and structure of protecting signal processing operations on safety-relevant data against transient or permanent bit errors, here called ‘watermarking’, where the input data is protected by a ‘watermarking function’ that (a) losslessly and reversibly encodes the data, (b) introduces information redundancy in the signal, (c) permits common (e.g. linear) mathematical operations on the watermarked data, (d) allows detection of at least one bit error in the operation, and (e) allows extraction of the intended mathematical result. A corresponding architecture may be less costly than the conventional method of hardening a calculation against transient faults, which is to brute-force duplicate the processing.

In further exemplary aspects an invertible ‘Watermarking function’ X=W(x) is applied to data signals x before performing intended mathematical operations on the watermarked signals X, and then applying the inverse function z=W′(Z) on the mathematical result Z to both (a) recover the intended exact result z and (b) detect any bit errors by checking the result's watermark redundancy property is intact. The watermarking function W(x) according to the present disclosure is chosen so that watermarked data X is compatible with common hardware arithmetic operations such as +,−,×, (with, at most, minor modifications), so that the computed results still satisfy the properties of error detection and data recoverability. More specifically, the data is multiplied by a small non-power-of-two value K such as 5 or 9. Watermarked (here, scaled-by-K) values may be processed in linear operations and retain the watermark multiple-of-K property; and if they are combined non-linearly (multiplying two of them together) a simple adaptation (to divide-by-K) returns them to the desired watermark state. Detection of single-bit errors may be straightforward: check modulo-K for zero; a nonzero K-modulus indicates error. And the inverse watermark function z=W′(Z) for final extraction of the desired result is a simple divide-by-K.

Aspects of the present disclosure include a signal processing circuit having a sender circuit configured to receive an input signal, transform the input signal to a first protected signal by multiplying an input value of the input signal by a first integer number greater than 2, and transmit the first protected signal, a receiver circuit configured to receive a second protected signal, transform the second protected signal to an output signal by dividing a protected value of the second protected signal by a second integer number greater than 2, determine whether an output value of the output signal is an integer number, and transmit the output signal in response to determining that the output value is an integer number, or transmit an error signal in response to determining that the output value is not an integer number.

Aspects of the present disclosure include the signal processing circuit above, wherein at least one of the first integer number or the second integer number is an odd number.

Aspects of the present disclosure include any of the signal processing circuits above, wherein at least one of the first integer number or the second integer number, in binary representation, has the least significant bit set to 1 and at least another bit set to 1.

Aspects of the present disclosure include any of the signal processing circuits above, wherein at least one of the first integer number or the second integer number, in binary representation, has the least significant bit set to 1 and at least two other bits set to 1.

Aspects of the present disclosure include any of the signal processing circuits above, wherein at least one of the first integer number or the second integer number is 5 or 9.

Aspects of the present disclosure include any of the signal processing circuits above, wherein at least one of the first integer number or the second integer number is 7, 11 or 13.

Aspects of the present disclosure include any of the signal processing circuits above, further comprising a sensor configured to receive the input signal and send the input signal to the sender circuit.

Aspects of the present disclosure include any of the signal processing circuits above, further comprising a controller configured to receive the output signal and generate a command making use of the output signal.

Aspects of the present disclosure include a method of processing signals including receiving an input signal, transforming the input signal to a first protected signal by multiplying an input value of the input signal by a first integer number greater than 2, transmitting the first protected signal, receiving a second protected signal, transforming the second protected signal to an output signal by dividing a protected value of the second protected signal by a second integer number greater than 2, determining whether an output value of the output signal is an integer number, and transmitting the output signal in response to determining that the output value is an integer number, or transmitting an error signal in response to determining that the output value is not an integer number.

Aspects of the present disclosure a non-transitory computer readable medium having instructions stored therein that, when executed by a processor, cause the processor to: cause a sender circuit to: receive an input signal, transform the input signal to a first protected signal by multiplying an input value of the input signal by a first integer number greater than 2, and transmit the first protected signal, and cause a receiver circuit to: receive a second protected signal, transform the second protected signal to an output signal by dividing a protected value of the second protected signal by a second integer number greater than 2, determine whether an output value of the output signal is an integer number, and transmit the output signal in response to determining that the output value is an integer number, or transmit an error signal in response to determining that the output value is not an integer number.

Aspects of the present disclosure may be performed by one or more of individual circuits, processors, memories (e.g., non-transitory computer readable medium), or other suitable devices. For example, one or more processors may execute instructions stored in the memories to perform one or more aspects of the present disclosure.

The term “processor,” as used herein, can refer to a device that processes signals and performs general computing and arithmetic functions. Signals processed by the processor can include digital signals, data signals, computer instructions, processor instructions, messages, a bit, a bit stream, or other computing that can be received, transmitted and/or detected. A processor, for example, can include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described herein.

The term “memory,” as used herein, can include volatile memory and/or nonvolatile memory. Non-volatile memory can include, for example, ROM (read only memory), PROM (programmable read only memory), EPROM (erasable PROM) and EEPROM (electrically erasable PROM). Volatile memory can include, for example, RAM (random access memory), synchronous RAM (SRAM), dynamic RAM (DRAM), synchronous DRAM (SDRAM), double data rate SDRAM (DDR SDRAM), and direct RAM bus RAM (DRRAM).

### VARIOUS NOTES & EXAMPLES

The above detailed description includes references to the accompanying drawings, which form a part of the detailed description. The drawings show, by way of illustration, specific implementations in which the invention may be practiced. These implementations are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, the terms “including” and “comprising” are open-ended, that is, a system, device, article, composition, formulation, or process that includes elements in addition to those listed after such a term are still deemed to fall within the scope of subject matter discussed. Moreover, such as may appear in a claim, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other implementations may be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of a claim. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed implementation. The following aspects are hereby incorporated into the Detailed Description as examples or implementations, with each aspect standing on its own as a separate implementation, and it is contemplated that such implementations may be combined with each other in various combinations or permutations.

What is claimed is:

1. A signal processing circuit, comprising:
a sender circuit configured to:
receive an input signal,
transform the input signal to a first protected signal by multiplying an input value of the input signal by a first integer number greater than 2, and
transmit the first protected signal;
a receiver circuit configured to:
receive a second protected signal,
transform the second protected signal to an output signal by dividing a protected value of the second protected signal by a second integer number greater than 2,
determine whether an output value of the output signal is an integer number, and
transmit the output signal in response to determining that the output value is an integer number, or
transmit an error signal in response to determining that the output value is not an integer number.

2. The signal processing circuit of claim 1, wherein at least one of the first integer number or the second integer number is an odd number.

3. The signal processing circuit of claim 1, wherein at least one of the first integer number or the second integer number, in binary representation, has the least significant bit set to 1 and at least another bit set to 1.

4. The signal processing circuit of claim 1, wherein at least one of the first integer number or the second integer number, in binary representation, has the least significant bit set to 1 and at least two other bits set to 1.

5. The signal processing circuit of claim 1, wherein at least one of the first integer number or the second integer number is 5 or 9.

6. The signal processing circuit of claim 1, wherein at least one of the first integer number or the second integer number is 7, 11 or 13.

7. The signal processing circuit of claim 1, further comprising a sensor configured to:
receive the input signal; and
send the input signal to the sender circuit.

8. The signal processing circuit of claim 1, further comprising a controller configured to:
receive the output signal; and
generate a command making use of the output signal.

9. A method of processing signals, comprising:
receiving an input signal;
transforming the input signal to a first protected signal by multiplying an input value of the input signal by a first integer number greater than 2;
transmitting the first protected signal;
receiving a second protected signal;
transforming the second protected signal to an output signal by dividing a protected value of the second protected signal by a second integer number greater than 2;
determining whether an output value of the output signal is an integer number; and
transmitting the output signal in response to determining that the output value is an integer number, or
transmitting an error signal in response to determining that the output value is not an integer number.

10. The method of claim 9, wherein at least one of the first integer number or the second integer number is an odd number.

11. The method of claim 9, wherein at least one of the first integer number or the second integer number, in binary representation, has the least significant bit set to 1 and at least another bit set to 1.

12. The method of claim 9, wherein at least one of the first integer number or the second integer number, in binary representation, has the least significant bit set to 1 and at least two other bits set to 1.

13. The method of claim 9, wherein at least one of the first integer number or the second integer number is 5 or 9.

14. The method of claim 9, wherein at least one of the first integer number or the second integer number is 7, 11 or 13.

15. The method of claim 9, further comprising:
receiving, by a sensor, the input signal; and
sending the input signal to the sender circuit.

16. The method of claim 9, further comprising:
receiving, by a controller, the output signal; and
generating a command making use of the output signal.

17. A non-transitory computer readable medium having instructions stored therein that, when executed by a processor, cause the processor to:
cause a sender circuit to:
receive an input signal,
transform the input signal to a first protected signal by multiplying an input value of the input signal by a first integer number greater than 2, and
transmit the first protected signal; and
cause a receiver circuit to:
receive a second protected signal,
transform the second protected signal to an output signal by dividing a protected value of the second protected signal by a second integer number greater than 2,
determine whether an output value of the output signal is an integer number, and
transmit the output signal in response to determining that the output value is an integer number, or
transmit an error signal in response to determining that the output value is not an integer number.

18. The non-transitory computer readable medium of claim 17, wherein at least one of the first integer number or the second integer number is an odd number.

19. The non-transitory computer readable medium of claim 17, wherein at least one of the first integer number or the second integer number, in binary representation, has the least significant bit set to 1 and at least another bit set to 1.

20. The non-transitory computer readable medium of claim 17, wherein at least one of the first integer number or the second integer number, in binary representation, has the least significant bit set to 1 and at least two other bits set to 1.
